(19) United States
(12) Patent Application Publication
(10) Pub. No.: US 2025/0357969 A1
(43) Pub. Date: Nov. 20, 2025

(54) Communication Method for Calibrating Sensor, Sensor and Sensor Assembly

(71) Applicant: Measurement Specialties (China) Ltd., Shenzhen City (CN)

(72) Inventors: Yibiao (Veally) Zhang, Shenzhen (CN); Youjun (York) Zeng, Shenzhen (CN); Wei Wang, Shenzhen (CN); Haijuan Dong, Shenzhen (CN)

(73) Assignee: Measurement Specialties (China) Ltd., Shenzhen City (CN)

(21) Appl. No.: 19/213,389

(22) Filed: May 20, 2025

(30) Foreign Application Priority Data
May 20, 2024 (CN) 202410627527.0

(51) Int. Cl. H04B 3/54; H04B 3/02

(52) U.S. Cl. CPC H04B 3/54; H04B 3/02

(57) ABSTRACT

A communication method for calibrating a sensor based on a power supply wire of the sensor includes modulating, by a calibration device, a command signal to be issued to the sensor into a voltage change signal. The voltage change signal is coupled onto the power supply wire of the sensor and the sensor receives the voltage change signal from the power supply wire. The communication method includes decoupling and demodulating the voltage change signal with the sensor to obtain the command signal, processing, by the sensor, the command signal after the sensor receives the command signal, and sending a corresponding command reply back to the calibration device.

### CROSS-REFERENCE TO RELATED APPLICATION

This application claims the benefit of the filing date under 35 U.S.C. § 119 (a)-(d) of Chinese Patent Application No. 202410627527.0, filed on May 20, 2024.

### FIELD OF THE INVENTION

Embodiments of the present disclosure relate to a communication method for calibrating a sensor based on a power supply wire of the sensor, and further, to a sensor and a sensor assembly including the sensor.

### BACKGROUND OF THE INVENTION

Existing sensor calibration communication methods typically require more than three cables, including one or two specialized communication cables, thereby resulting in additional material and production costs. In addition, in the existing sensor communication methods, the communication cable is usually cut after the sensor is adjusted and when the sensor is assembled, so that the assembled sensor cannot be calibrated, thus, there is a risk of product scrap or failure. In addition, the existing sensor communication methods have poor anti-interference performance and are difficult to adapt to long communication cables.

### SUMMARY OF THE INVENTION

A communication method for calibrating a sensor based on a power supply wire of the sensor includes modulating, by a calibration device, a command signal to be issued to the sensor into a voltage change signal. The voltage change signal is coupled onto the power supply wire of the sensor and the sensor receives the voltage change signal from the power supply wire. The communication method includes decoupling and demodulating the voltage change signal with the sensor to obtain the command signal, processing, by the sensor, the command signal after the sensor receives the command signal, and sending a corresponding command reply back to the calibration device.

### BRIEF DESCRIPTION OF THE DRAWINGS

The invention will now be described by way of example with reference to the accompanying figures, of which:

FIG. 1 is a schematic view showing a communication method for calibrating a sensor based on a power supply wire of the sensor according to an exemplary embodiment of the present disclosure;

FIG. 2 is a circuit diagram showing a communication method for calibrating a sensor based on a power supply wire of the sensor according to an exemplary embodiment of the present disclosure; and

FIG. 3 is a flow diagram showing a communication method for calibrating a sensor based on a power supply wire of the sensor according to an exemplary embodiment of the present disclosure.

### DETAILED DESCRIPTION

Although the present disclosure will be fully described with reference to the drawings containing embodiments of the present disclosure, it should be understood that those skilled in the art may modify the present disclosure described herein while obtaining the technical effect of the present disclosure. Therefore, it is necessary to understand that the description herein is a broad disclosure for those skilled in the art and is not intended to limit the exemplary embodiments described in the present disclosure.

In addition, in the following detailed description, for the sake of explanation, numerous specific details are set forth in order to provide a thorough understanding of the disclosed embodiments. It will be apparent, however, that one or more embodiments may also be practiced without these specific details. In other instances, well-known structures and devices are illustrated schematically in order to simplify the drawing.

As there may be manufacturing differences in sensors of the same type, the sensors usually need to undergo an accurate calibration process before leaving the factory to ensure their performance and measurement accuracy, and to meet the user's needs for quality and reliability. The outputs of the sensors of the same type can be more consistent after the calibration, which enhances the unity of the product, and facilitates the application and maintenance for the users. A sensor in the related art typically includes a sensor body and a power supply wire connected to the sensor body, the power supply wire being configured to be connected with a power supply to supply power to the sensor body.

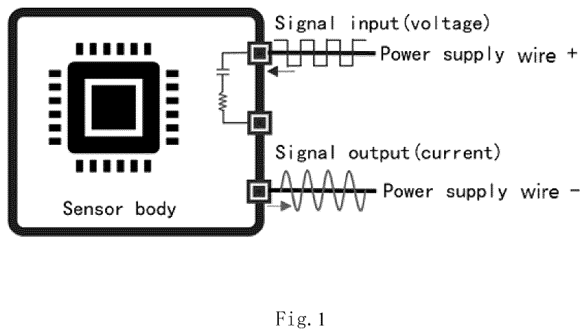

Referring to FIG. 1 to FIG. 3, according to exemplary embodiments of the present disclosure, there is provided a communication method for calibrating a sensor based on a power supply wire of the sensor. The method includes:
S1: modulating, by a calibration device, a command signal to be issued to the sensor into a voltage change signal, and coupling the voltage change signal onto the power supply wire (i.e., “power supply wire+” as shown in FIG. 1) of the sensor;
S2: receiving, by the sensor, the voltage change signal from the power supply wire, and decoupling and demodulating the voltage change signal to obtain the command signal; and
S3: processing, by the sensor, the command signal after the sensor receives the command signal, and sending a corresponding command reply back to the calibration device.

In this way, the power supply of the sensor is realized via the power supply wire, while the calibration device modulates the command signal to be issued to the sensor into the voltage change signal and couples the voltage change signal onto the power supply wire of the sensor, so as to achieve the sending of the communication signal to the sensor, namely, the power supply wire of the sensor itself is reused. As a result, the communication cable specialized for the signal transmission is saved, thereby saving the materials and reducing the production cost. And, after the sensor is assembled, the communication signal can still be sent to the sensor via the power supply wire, so as to recalibrate the sensor to reduce the risk of finished product scrap. It should be noted that, in some other embodiments of the present disclosure, the calibration device may also modulate the command signal to be issued to the sensor into a current change signal and couple the current change signal onto the power supply wire of the sensor so as to achieve the sending of the communication signal to the sensor.

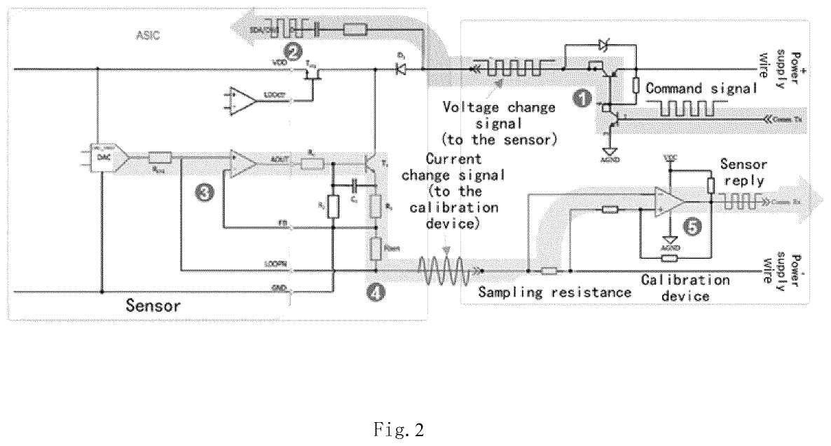

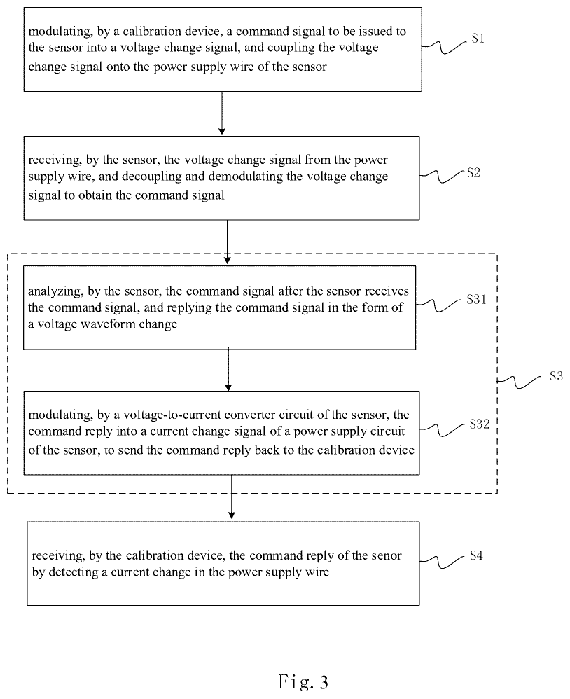

In an exemplary embodiment of the present disclosure, referring to FIG. 2 to FIG. 3, processing, by the sensor, the command signal after the sensor receives the command signal, and sending a corresponding command reply back to the calibration device, includes:
S31: analyzing, by the sensor, the command signal after the sensor receives the command signal, and replying the command signal in the form of a voltage waveform change; and
S32: modulating, by a voltage-to-current converter circuit of the sensor, the command reply into a current change signal of a power supply circuit (i.e, “power supply wire-” as shown in FIG. 1) of the sensor, to send the command reply back to the calibration device.

In the communication method for calibrating the sensor, by modulating the current change in the power supply circuit of the sensor itself, the command reply is sent back to the calibration device, thereby saving the communication cable that sends the command reply back to the calibration device, further saving the materials and reducing the production cost. Furthermore, according to the embodiments of the present disclosure, the communication method for calibrating the sensor modulates the command signal from the calibration device into the voltage change signal and coupling it onto the power supply wire (i.e, “power supply wire+” as shown in FIG. 1) of the sensor itself, and modulates the command reply into the current change signal of the power supply circuit (i.e, “power supply wire-” as shown in FIG. 1), which enhances the anti-interference of the communication method and adapts to communication cables with different lengths.

In an exemplary embodiment of the present disclosure, the method may further include: S4: receiving, by the calibration device, the command reply of the senor by detecting a current change in the power supply circuit (i.e, “power supply wire-” as shown in FIG. 1).

In particular, according to the embodiments of the present disclosure, the voltage change signal from the calibration device and on the power supply wire is decoupled and demodulated by the sensor via a resistance-capacitance circuit, to obtain the command signal.

In an exemplary embodiment of the present disclosure, the voltage change signal has a high voltage level of 24V and a low voltage level of 16V. It should be noted that in other embodiments of the present disclosure, the high voltage level and the low voltage level of the voltage change signal may also be other values, and the specific values may be designed according to the specific cases.

In an exemplary embodiment of the present disclosure, the voltage change signal has a duty cycle of 0.75. It should be noted that in other embodiments of the present disclosure, the duty ratio of the voltage change signal may also be other values, and the specific values may be designed according to the specific cases.

In an exemplary embodiment of the present disclosure, the current change signal has a high current level of 16 mA and a low current level of 6 mA. It should be noted that in other embodiments of the present disclosure, the high current level and the low current level of the current change signal may also be other values, and the specific values may be designed according to the specific cases.

In an exemplary embodiment of the present disclosure, the sensor is at least one of a 2-wire current sensor, a 3-wire current sensor, a voltage analog sensor, and a digital sensor.

According to another aspect of the present disclosure, there is also provided a sensor being calibrated using the method according to the embodiments of the present disclosure.

According to yet another aspect of the present disclosure, there is further provided a sensor assembly including: the sensor according to the present disclosure; and a calibration device configured to calibrate the sensor.

According to the communication method for calibrating the sensor according to the abovementioned embodiments of the present disclosure, the sending of the communication signal to the sensor is achieved by modulating the command signal into the voltage change signal and coupling the voltage change signal onto the power supply wire of the sensor itself, namely, the power supply wire of the sensor itself is reused. As a result, the communication cable specialized for the signal transmission is saved, thereby saving the materials and reducing the production cost. Further, in the communication method for calibrating the sensor, by modulating the current change in the power supply circuit of the sensor itself, the command reply is sent back to the calibration device, thus saving the communication cable that sends the command reply back to the calibration device, thereby further saving the materials and reducing the production cost. Furthermore, the sensor can be recalibrated at any time (even after the sensor is assembled), which reduces the risk of the finished product scrap. In addition, the communication method for calibrating the sensor according to the embodiments of the present disclosure modulates the command signal from the calibration device into the voltage change signal and coupling it onto the power supply wire of the sensor itself, and modulates the command reply into the current change signal of the power supply circuit, which enhances the anti-interference of the communication method and adapts to communication cables with different lengths.

It should be appreciated by those skilled in the art that the above embodiments are intended to be illustrative, and many modifications may be made to the above embodiments by those skilled in the art. Further, various structures described in various embodiments may be freely combined with each other without conflicting in configuration or principle.

Although the present disclosure has been described hereinbefore in detail with reference to the accompanying drawings, it should be appreciated that the disclosed embodiments in the accompanying drawings are intended to illustrate embodiments of the present disclosure by way of example, and should not be construed as a limitation to the present disclosure.

Although some embodiments of the general inventive concept of the present disclosure have been shown and described, it would be appreciated by those skilled in the art that changes or modifications may be made to these embodiments without departing from the principles and spirit of the general inventive concept, the scope of which is defined in the claims and their equivalents.

It should be noted that, the word “comprise” or “include” doesn't exclude other elements or steps, and the word “a” or “an” doesn't exclude more than a plurality. In addition, any reference numerals in the claims should not be interpreted as the limitation to the scope of the present disclosure.

1. A communication method for calibrating a sensor based on a power supply wire of the sensor, the method comprising:
modulating, by a calibration device, a command signal to be issued to the sensor into a voltage change signal;
coupling the voltage change signal onto the power supply wire of the sensor;
receiving, by the sensor, the voltage change signal from the power supply wire;
decoupling and demodulating the voltage change signal with the sensor to obtain the command signal;
processing, by the sensor, the command signal after the sensor receives the command signal; and
sending a corresponding command reply back to the calibration device.

2. The communication method of claim 1, wherein the processing step includes analyzing, by the sensor, the command signal after the sensor receives the command signal, and generating the command signal in the form of a voltage waveform change.

3. The communication method of claim 2, wherein the processing step includes modulating, by a voltage-to-current converter circuit of the sensor, the corresponding command reply into a current change signal of a power supply circuit of the sensor.

4. The communication method of claim 3, further comprising receiving, by the calibration device, the corresponding command reply of the senor by detecting a current change in the power supply wire.

5. The communication method of claim 3, wherein, in the decoupling and demodulating step, the voltage change signal from the calibration device on the power supply wire is decoupled and demodulated by the sensor via a resistance-capacitance circuit, to obtain the command signal.

6. The communication method of claim 2, wherein the voltage change signal has a high voltage level of 24V.

7. The communication method of claim 6, wherein the voltage change signal has a low voltage level of 16V.

8. The communication method of claim 2, wherein the voltage change signal has a duty cycle of 0.75.

9. The communication method of claim 2, wherein the current change signal has a high current level of 16 mA.

10. The communication method of claim 9, wherein the current change signal has a low current level of 6 mA.

11. The communication method of claim 1, wherein the sensor is at least one of a 2-wire current sensor, a 3-wire current sensor, a voltage analog sensor, and a digital sensor.

12. The communication method of claim 2, wherein the sensor is at least one of a 2-wire current sensor, a 3-wire current sensor, a voltage analog sensor, and a digital sensor.

13. A sensor calibrating according to a method, comprising:
modulating, by a calibration device, a command signal to be issued to the sensor into a voltage change signal;
coupling the voltage change signal onto a power supply wire of the sensor;
receiving, by the sensor, the voltage change signal from the power supply wire;
decoupling and demodulating the voltage change signal with the sensor to obtain the command signal;
processing, by the sensor, the command signal after the sensor receives the command signal; and
sending a corresponding command reply back to the calibration device.

14. The sensor of claim 13, wherein the processing step includes analyzing, by the sensor, the command signal after the sensor receives the command signal, and generating the command signal in the form of a voltage waveform change.

15. The sensor of claim 14, wherein the processing step includes modulating, by a voltage-to-current converter circuit of the sensor, the corresponding command reply into a current change signal of a power supply circuit of the sensor.

16. A sensor assembly, comprising:
a calibration device; and
a sensor calibrated according to the steps of:
modulating, by the calibration device, a command signal to be issued to the sensor into a voltage change signal;
coupling the voltage change signal onto a power supply wire of the sensor;
receiving, by the sensor, the voltage change signal from the power supply wire;
decoupling and demodulating the voltage change signal with the sensor to obtain the command signal;
processing, by the sensor, the command signal after the sensor receives the command signal; and
sending a corresponding command reply back to the calibration device.

17. The sensor assembly of claim 16, wherein the processing step includes analyzing, by the sensor, the command signal after the sensor receives the command signal, and generating the command signal in the form of a voltage waveform change.

18. The sensor assembly of claim 17, wherein the processing step includes modulating, by a voltage-to-current converter circuit of the sensor, the corresponding command reply into a current change signal of a power supply circuit of the sensor.
